(19) United States
(12) Patent Application Publication
(10) Pub. No.: US 2013/0075923 A1
(43) Pub. Date: Mar. 28, 2013

(54) INTEGRATED CIRCUIT PACKAGING SYSTEM WITH ENCAPSULATION AND METHOD OF MANUFACTURE THEREOF

(71) Applicants: YeongIm Park, Yongin-city (KR); HeeJo Chi, Ichon-si (KR); HyungMin Lee, Bucheon-si (KR)

(72) Inventors: YeongIm Park, Yongin-city (KR); HeeJo Chi, Ichon-si (KR); HyungMin Lee, Bucheon-si (KR)

(21) Appl. No.: 13/243,555

(22) Filed: Sep. 23, 2011

(51) Int. Cl. H01L 23/48; H01L 21/56

(52) U.S. Cl. 257/774; 438/108; 257/E21.502; 257/E23.011

(57) ABSTRACT

A method of manufacture of an integrated circuit packaging system includes: providing a substrate having a substrate first side and a substrate second side opposite the substrate first side; attaching a base integrated circuit to the substrate first side; attaching a mountable integrated circuit to the substrate second side; attaching a via base to the substrate second side adjacent the mountable integrated circuit; forming a device encapsulation surrounding the via base and the mountable integrated circuit; and forming a via extension through the device encapsulation and attached to the via base, the via extension exposed from the device encapsulation.

### TECHNICAL FIELD

The present invention relates generally to an integrated circuit packaging system, and more particularly to a system for interconnects.

### BACKGROUND ART

Increased miniaturization of components, greater packaging density of integrated circuits (“ICs”), higher performance, and lower cost are ongoing goals of the computer industry. Semiconductor package structures continue to advance toward miniaturization, to increase the density of the components that are packaged therein while decreasing the sizes of the products that are made using the semiconductor package structures. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made smaller and thinner as well.

Many conventional semiconductor (or “chip”) packages are of the type where a semiconductor die is molded into a package with a resin, such as an epoxy molding compound. Numerous package approaches stack multiple integrated circuit dice or package in package (PIP) or a combination. Other approaches include package level stacking or package-on-package (POP). POP designs face reliability challenges and higher cost.

Thus, a need still remains for an integrated circuit system improved yield, low profile, and improved reliability. In view of the ever-increasing commercial competitive pressures, along with growing consumer expectations and the diminishing opportunities for meaningful product differentiation in the marketplace, it is increasingly critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a substrate having a substrate first side and a substrate second side opposite the substrate first side; attaching a base integrated circuit to the substrate first side; attaching a mountable integrated circuit to the substrate second side; attaching a via base to the substrate second side adjacent the mountable integrated circuit; forming a device encapsulation surrounding the via base and the mountable integrated circuit; and forming a via extension through the device encapsulation and attached to the via base, the via extension exposed from the device encapsulation.

The present invention provides an integrated circuit packaging system, including: a substrate having a substrate first side and a substrate second side opposite the substrate first side; a base integrated circuit attached to the substrate first side; a mountable integrated circuit attached to the substrate second side; a via base attached to the substrate second side adjacent the mountable integrated circuit; a device encapsulation surrounding the via base and the mountable integrated circuit; and a via extension through the device encapsulation and attached to the via base, the via extension exposed from the device encapsulation.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a top view of an integrated circuit packaging system in a first embodiment of the present invention.

FIG. 2 is a cross-sectional view of the integrated circuit packaging system along line 2-2 of FIG. 1.

FIG. 3 is a bottom view of the integrated circuit packaging system.

FIG. 4 is a top view of an integrated circuit packaging system in a second embodiment of the present invention.

FIG. 5 is a cross-sectional view of the integrated circuit packaging system along line 5-5 of FIG. 4.

FIG. 6 is a cross-sectional view of an integrated circuit packaging system as exemplified by the top view along line 2-2 of FIG. 1 in a third embodiment of the present invention.

FIG. 7 is a cross-sectional view of an integrated circuit packaging system as exemplified by the top view along line 2-2 of FIG. 1 in a fourth embodiment of the present invention.

FIG. 8 is a top view of an integrated circuit packaging system in a fifth embodiment of the present invention.

FIG. 9 is a cross-sectional view of the integrated circuit packaging system along line 9-9 of FIG. 8.

FIG. 10 is a cross-sectional view of a portion of the integrated circuit packaging system along line 2-2 of FIG. 1 in an attaching phase.

FIG. 11 is the structure of FIG. 10 in a molding phase.

FIG. 12 is the structure of FIG. 11 in an attaching phase.

FIG. 13 is shown the structure of FIG. 12 in a further attaching phase.

FIG. 14 is shown the structure of FIG. 13 in a further molding phase.

FIG. 15 is shown the structure of FIG. 14 in a forming the integrated circuit packaging system 100 of FIG. 1

FIG. 16 is a flow chart of a method of manufacture of the integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit active side, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements or components with no intervening material.

The term “processing” as used herein includes deposition of material or photoresist, patterning, exposure, development, etching, cleaning, and/or removal of the material or photoresist as required in forming a described structure.

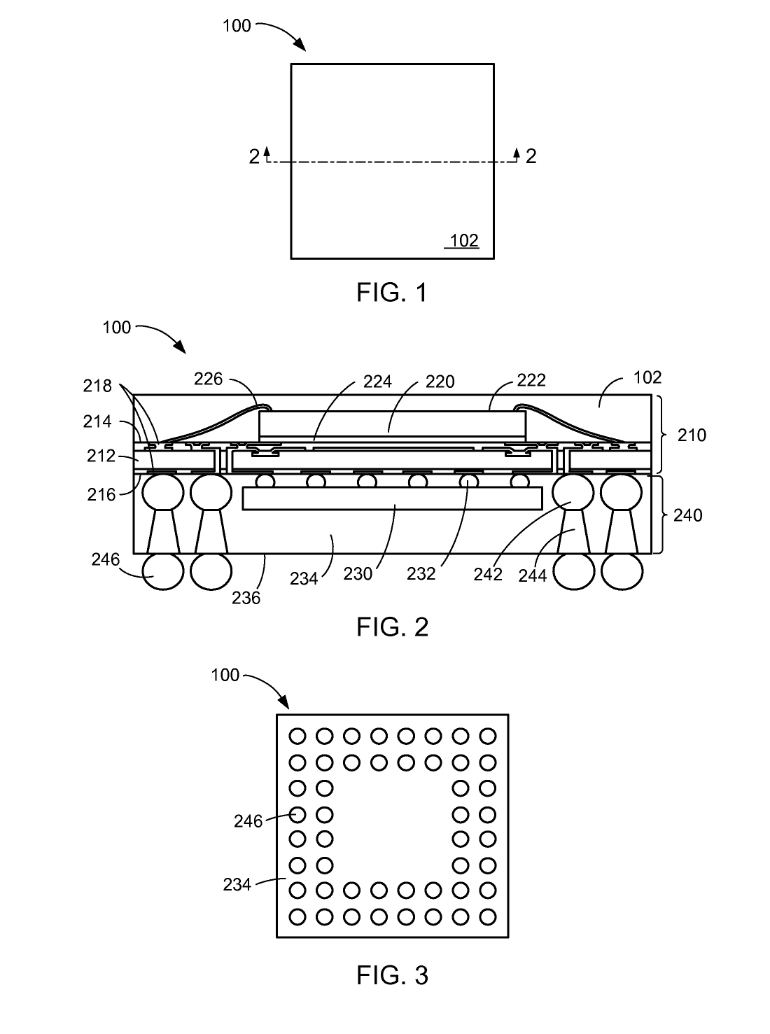

Referring now to FIG. 1, therein is shown a top view of an integrated circuit packaging system 100. The top view depicts a circuit encapsulation 102. The circuit encapsulation 102 is defined as a protective cover having electrical and environmental insulating properties providing a hermetic seal. As an example, the circuit encapsulation 102 can be a molded encapsulation material, such as an epoxy molding compound or ceramic material.

For illustrative purposes, the integrated circuit packaging system 100 is shown with the circuit encapsulation 102 having a square geometric shape although it is understood that the circuit encapsulation 102 can have a different geometric shape. For example, the circuit encapsulation 102 can have a rectangular geometric shape or an octagonal geometric shape.

Referring now to FIG. 2, therein is shown a cross-sectional view of the integrated circuit packaging system 100 along line 2-2 of FIG. 1. The cross-sectional view depicts an integrated circuit structure 210. The integrated circuit structure 210 is defined as a structure including an interposer and an active device having active circuitry thereon.

The integrated circuit structure 210 can include a substrate 212. The substrate 212 is defined as a rigid structure that provides support and connectivity for mounting other components and devices. As an example, the substrate 212 can be a laminated substrate or a ceramic substrate. As a further example, the laminated substrate can be a layered substrate having vias and intermetallic layers. As a specific example, the substrate 212 can be a printed circuit board.

The substrate 212 can have a substrate first side 214 and a substrate second side 216. The substrate first side 214 and the substrate second side 216 can be the opposing horizontal sides of the substrate 212 with the substrate second side 216 facing away from the substrate first side 214.

Contact pads 218 can be exposed along the substrate first side 214 and the substrate second side 216. The contact pads 218 are defined as conductive pads that provide electrical connectivity between the substrate 212 and other devices or structures.

The integrated circuit structure 210 can include a base integrated circuit 220 attached to the substrate 212. The base integrated circuit 220 is defined as an active device having active circuitry fabricated thereon. As an example, the base integrated circuit 220 can be a semiconductor die, a thin semiconductor die, a wirebond die, or a flip chip.

The base integrated circuit 220 can have a circuit active side 222. The circuit active side 222 is defined as the side of the base integrated circuit 220 having active circuitry fabricated thereon (not shown). The circuit active side 222 can face away from the substrate first side 214. The circuit active side 222 can be parallel with the substrate first side 214.

The base integrated circuit 220 can be attached to the substrate first side 214 with an adhesive 224. The adhesive 224 is defined as a material for physically bonding or adhering two or more components to each other. For example, the adhesive 224 can be an epoxy or polymer adhesive material, a B-stage or partially cured adhesive material, or a thermally conductive adhesive material. The adhesive 224 can be between the substrate first side 214 and the base integrated circuit 220.

Circuit interconnects 226 can connect the base integrated circuit 220 to the substrate 212. The circuit interconnects 226 are defined as conductive structures for providing electrical connection between elements, devices, and other structures. As an example, the circuit interconnects 226 can be bond wires or ribbon bond wires. The circuit interconnects 226 can be connected between the circuit active side 222 and the contact pads 218 exposed along the substrate first side 214.

The integrated circuit structure 210 can include the circuit encapsulation 102. The circuit encapsulation 102 can be on and cover the substrate first side 214. The circuit encapsulation 102 can be on and surround the base integrated circuit 220 and the circuit interconnects 226. The circuit encapsulation 102 can form a hermetic seal around the base integrated circuit 220 and the circuit interconnects 226.

A mountable integrated circuit 230 can be attached to the substrate 212 of the integrated circuit structure 210. The mountable integrated circuit 230 is defined as an active device having active circuitry fabricated thereon. As an example, the mountable integrated circuit 230 can be a semiconductor die, a thin semiconductor die, a wirebond die, or a flip chip.

The mountable integrated circuit 230 can be attached to the substrate second side 216 with device interconnects 232. The device interconnects are defined as conductive structures that provide electrical connection between elements, devices, and other structures. As an example, the device interconnects 232 can be solder balls, solder bumps, conductive pillars, or conductive bumps. The device interconnects 232 can be between the substrate second side 216 and the mountable integrated circuit 230.

A device encapsulation 234 can be on and cover the substrate second side 216. The device encapsulation 234 is defined as a protective cover having electrical and environmental insulating properties providing a hermetic seal. As an example, the device encapsulation 234 can be a molded encapsulation material, such as an epoxy molding compound or ceramic material.

The device encapsulation 234 can be on and surround the mountable integrated circuit 230. The device encapsulation 234 can fill the space between the mountable integrated circuit 230 and the substrate second side 216. The device encapsulation 234 can surround the device interconnects 232. The device encapsulation 234 can form a hermetic seal around the mountable integrated circuit 230 and the device interconnects 232. The device encapsulation 234 surrounding the device interconnects 232 and between the mountable integrated circuit 230 and the substrate 212 can form a molded underfill.

The device encapsulation 234 can have an encapsulation outer side 236. The encapsulation outer side 236 is defined as the side of the device encapsulation 234 facing away from the substrate 212 of the integrated circuit structure 210. The encapsulation outer side 236 can be parallel with the substrate second side 216.

Via structures 240 can be in and surrounded by the device encapsulation 234. The via structures 240 are defined as conductive structures in a protective cover that provide electrical connectivity and extend between a side of a substrate and a surface of the protective cover.

The via structures 240 can be attached to the substrate 212 of the integrated circuit structure 210 at one end of the via structures 240 and exposed from the device encapsulation 234 at the opposing end of the via structures 240. The via structures 240 can extend vertically through the device encapsulation 234. The via structures 240 can be adjacent to the vertical sides of the mountable integrated circuit 230.

The via structures 240 can be formed from two separate conductive structures including a via base 242 and a via extension 244. The via base 242 is defined as the portion of the via structures 240 that provides connection to electrical connection sites on a support structure. The via base 242 can be the portion of the via structures 240 on the substrate second side 216. As an example, the via base 242 can be a conductive bump, conductive post, or conductive pillar. As a further example, the via base 242 can be formed from conductive materials, such as solder, gold, gold alloys, silver, silver alloys, or other alloys.

The via base 242 can be electrically connected to the contact pads 218 exposed along the substrate second side 216. The via base 242 can protect the contact pads 218 from damage due to physical, mechanical, chemical, or other processing when forming the via structures 240 on the substrate 212.

For illustrative purposes, the via base 242 is shown having a rounded or circular geometric shape, although it is understood that the via base 242 can have a different shape. For example, the via base 242 can have a rectangular profile corresponding to a cylindrical or rectangular block shape in three dimensional space.

For further illustrative purposes, the via base 242 is shown having a length in the vertical dimension as measured from the substrate second side 216 to the portion of the via base 242 directly opposite the substrate second side 216. Further, the length of the via base 242 is shown as similar or equivalent to the distance between the substrate second side 216 and the side of the mountable integrated circuit 230 facing away from the substrate second side 216 although it is understood that the via base 242 can have a different length.

For example, the via base 242 can have the length where the vertical length of the via structure 240 in the vertical direction, as measured from the substrate second side 216, is similar or equivalent to the distance between the substrate second side 216 and the side of the mountable integrated circuit 230 facing away from the substrate second side 216. As a further example, the length of the via base 242 can be greater than the distance between the substrate second side 216 and the side of the mountable integrated circuit 230 facing away from the substrate second side 216. As a specific example, the length of the via base 242 can be increased to reduce the length of the via extension 244, which can reduce the manufacturing time when forming the via extension 244.

The via base 242 can connect the via extension 244 of the via structures 240 to the integrated circuit structure 210. The via extension 244 can be the portion of the via structures 240 that extends between the via base 242 and the horizontal surface of the device encapsulation 234 facing away from the integrated circuit structure 210. The via base 242 and the via extension 244 can form a continuous conductive structure from the substrate 212 to the encapsulation outer side 236.

The via extension 244 can be attached to the via base 242 on one end and exposed from the device encapsulation 234 on the opposing end. The exposed portion of the via extension 244 can be coplanar with the encapsulation outer side 236 of the device encapsulation 234.

The via extension 244 can be a conductive structure formed from a hole or channel (not shown) filled with conductive material and extending from the encapsulation outer side 236 of the device encapsulation 234 to the via base 242. As an example, the via extension 244 can be made from conductive material, such as a conductive paste including copper or silver epoxy compounds, copper alloys, gold or gold alloys, or a low melting temperature high-wicking solder alloy. The via extension 244 can be made from a material having a melting point higher than that of the via base 242 or made from a material having higher resistant to flow and deformation at elevated temperatures relative to the via base 242.

As a further example, the hole or channel in the device encapsulation 234 can be formed by a laser ablation process, chemical etching, or mechanical processing, such as drilling. The interface between the device encapsulation 234 and the via extension 244 can have the characteristics of an encapsulation material removed. The characteristics of the encapsulation removed can include chemical residue, etching marks, groves, localized physical degradation or decomposition from exposure to high temperatures.

The via extension 244 can have a tapered shape along the vertical length of the via extension 244. A tapered shape is defined as a shape having a narrowing width with one end having a greater width than that of the opposing end. For example, the portion of the via extension 244 exposed from the device encapsulation 234 can have a width greater than that of the portion of the via extension 244 attached to the via base 242.

The via extension 244 can act as a barrier that maintains the position and form of the via base 242. For example, the via extension 244 can retain the shape of the via base 242 and prevent the flow or deformation of the via base 242 during processing of the integrated circuit packaging system 100 that would cause the via base 242 to melt or transition from a solid state to a liquid state, such as a solder reflow process.

External interconnects 246 can be connected to the via structures 240. The external interconnects 246 are defined as conductive connectors that provide connectivity between a packaging system and other devices and components. As an example, the external interconnects 246 can be solder balls, solder bumps, conductive pillars, or conductive bumps. The external interconnects 246 can connect the integrated circuit packaging system 100 to a next system level down (not shown). The external interconnects 246 can be attached on the portion of the via structures 240 exposed along the encapsulation outer side 236.

It has been discovered that the base integrated circuit 220 attached to the substrate first side 214 and the mountable integrated circuit 230 attached to the substrate second side 216 increases package density and reduces overall package height by eliminating the need for additional mounting and connecting structures that reduce package density and increase overall package height.

It has also been discovered that the via structures 240 having the via base 242 on the contact pads 218 of the substrate 212 protects the contact pads 218 from processing when forming the via structures 240.

It has been further discovered that the via structures 240 having the via extension 244 maintains the connection integrity between the via base 242 and the contact pads 218 by retaining the shape of the via base 242, and thus connection to the contact pads 218, during reflow processes, such as connection of the external interconnects 246 to the via extension 244.

It has been further discovered that the via extension 244 having the tapered shape improves electrical connectivity by providing a broader connection surface between the via structures 240 and the external interconnects 246.

It has been further discovered that the via extension 244 having the tapered shape reduces the size of the via structures 240 by reducing the area of the attachment interface between the via extension 244 and the via base 242 compared to the wider end of the via extension 244, which reduces the size needed for the via base 242.

It has been further discovered that the device encapsulation 234 surrounding the device interconnects 232 and between the mountable integrated circuit 230 and the substrate 212 can form the molded underfill, which reduces processing time by eliminating an additional process step required to form a separate underfill.

Referring now to FIG. 3, therein is shown a bottom view of the integrated circuit packaging system 100. The bottom view depicts the external interconnects 246 attached to the via structures 240 of FIG. 2. The external interconnects 246 and the via structures 240 can be arranged in rows along the perimeter of the device encapsulation 234.

For illustrative purposes, the integrated circuit packaging system 100 is shown having the external interconnects 246 and the via structures 240 arranged in dual rows along the perimeter of the device encapsulation 234, although it is understood that the external interconnects 246 and the via structures 240 can be arranged differently. For example, the external interconnects 246 and the via structures 240 can be arranged in a single row or can include three or more rows. In a further example, the external interconnects 246 and the via structures 240 can be arranged in a staggered configuration.

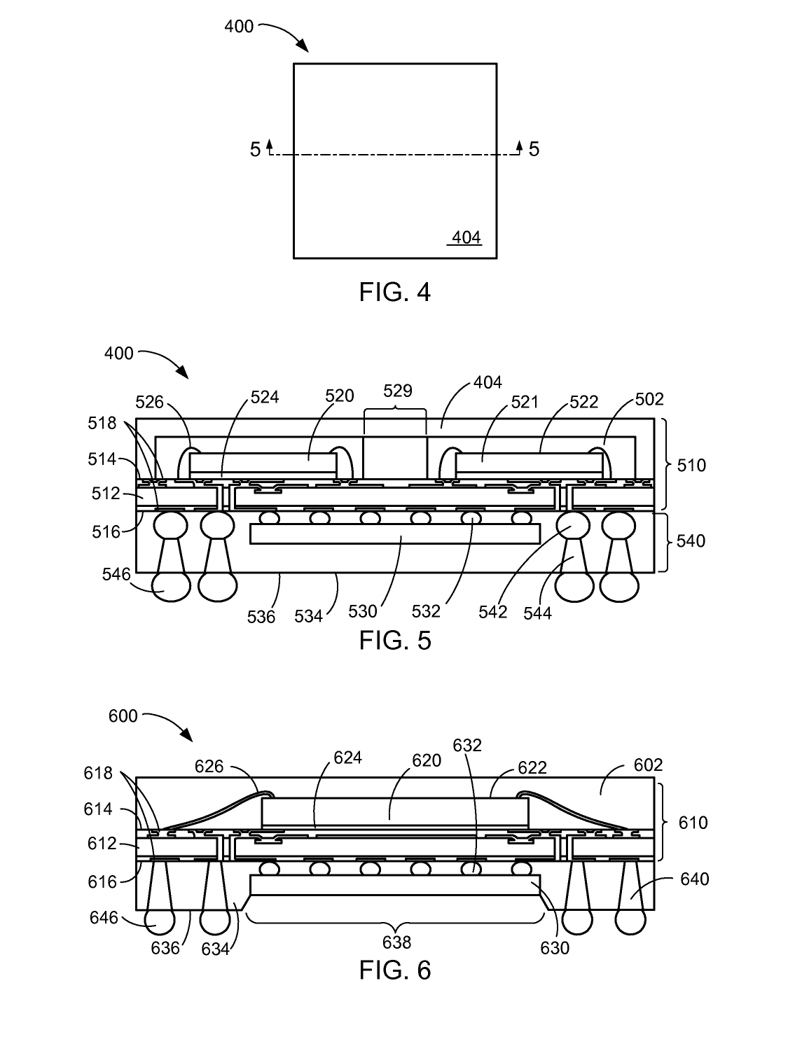

Referring now to FIG. 4, therein is shown a top view of an integrated circuit packaging system 400 in a second embodiment of the present invention. The top view depicts a conductive cover 404. The conductive cover 404 is defined as a conducive cover having thermally and electrically conductive properties for enhancing heat dissipation, protecting components and device from electromagnetic interference, or a combination thereof. As an example, the conductive cover 404 can be a heat spreader, heat sink, or an electromagnetic shield. The conductive cover 404 can be made from conductive material, such as metal or metal alloys including copper, copper alloy, aluminum, alloy, or other thermally and electrically conductive materials.

For illustrative purposes, the integrated circuit packaging system 400 is shown with the conductive cover 404 having a square geometric shape although it is understood that the conductive cover 404 can have a different geometric shape. For example, the conductive cover 404 can have a rectangular geometric shape or an octagonal geometric shape.

Referring now to FIG. 5, therein is shown a cross-sectional view of the integrated circuit packaging system 400 along line 5-5 of FIG. 4. The cross-sectional view depicts an integrated circuit structure 510. The integrated circuit structure 510 is defined as a structure including interposer and an active device having active circuitry thereon.

The integrated circuit structure 510 can include a substrate 512. The substrate 512 is defined as a rigid structure that provides support and connectivity for mounting other components and devices. As an example, the substrate 512 can be a laminated substrate or a ceramic substrate. As a further example, the laminated substrate can be a layered substrate having vias and intermetallic layers. As a specific example, the substrate 512 can be a printed circuit board.

The substrate 512 can have a substrate first side 514 and a substrate second side 516. The substrate first side 514 and the substrate second side 516 can be the opposing horizontal sides of the substrate 512 with the substrate second side 516 facing away from the substrate first side 514.

Contact pads 518 can be exposed along the substrate first side 514 and the substrate second side 516. The contact pads 518 are defined as conductive pads that provide electrical connectivity between the substrate 512 and other devices or structures.

The integrated circuit structure 510 can include a first base integrated circuit 520 and a second base integrated circuit 521. The first base integrated circuit 520 and the second base integrated circuit 521 are defined as active devices having active circuitry fabricated thereon. As an example, the first base integrated circuit 520 and the second base integrated circuit 521 can be semiconductor die, thin semiconductor die, wirebond die, or flip chips. The first base integrated circuit 520 and the second base integrated circuit 521 can be attached to the substrate 512 and horizontally adjacent to one another.

The first base integrated circuit 520 and the second base integrated circuit 521 can each have a circuit active side 522. The circuit active side 522 is defined as the side of the first base integrated circuit 520 and the second base integrated circuit 521 having active circuitry fabricated thereon (not shown). The circuit active side 522 of the first base integrated circuit 520 and the second base integrated circuit 521 can face away from the substrate first side 514. The circuit active side 522 can be parallel with the substrate first side 514.

The first base integrated circuit 520 and the second base integrated circuit 521 can be attached to the substrate first side 514 with an adhesive 524. The adhesive 524 is defined as a material for physically bonding or adhering two or more components to each other. For example, the adhesive 524 can be an epoxy or polymer adhesive material, a B-stage or partially cured adhesive material, or a thermally conductive adhesive material. The adhesive 524 can be between the substrate first side 514 and the first base integrated circuit 520 and the second base integrated circuit 521.

Circuit interconnects 526 can connect the first base integrated circuit 520 and the second base integrated circuit 521 to the substrate 512. The circuit interconnects 526 are defined as conductive structures for providing electrical connection between elements, devices, and other structures. As an example, the circuit interconnects 526 can be bond wires or ribbon bond wires. The circuit interconnects 526 can be connected between the circuit active side 522 and the contact pads 518 exposed along the substrate first side 514.

The integrated circuit structure 510 can include a circuit encapsulation 502. The circuit encapsulation 502 is defined as a protective cover having electrical and environmental insulating properties providing a hermetic seal. As an example, the circuit encapsulation 502 can be a molded encapsulation material, such as an epoxy molding compound or ceramic material.

The circuit encapsulation 502 can be on and cover the substrate first side 514. The circuit encapsulation 502 can be on and surround the first base integrated circuit 520 and the second base integrated circuit 521 and the circuit interconnects 526. The circuit encapsulation 502 can form a hermetic seal around the first base integrated circuit 520 and the second base integrated circuit 521 and the circuit interconnects 526.

The circuit encapsulation 502 can be an encapsulation gap 529 between the first base integrated circuit 520 and the second base integrated circuit 521. The encapsulation gap 529 can expose a portion of the substrate first side 514 between the first base integrated circuit 520 and the second base integrated circuit 521.

The conductive cover 404 can be attached to the substrate 512 along the perimeter of the substrate first side 514. The conductive cover 404 can be electrically connected to the contact pads 518 exposed along the substrate first side 514. The contact pads 518 connected to the conductive cover 404 can be electrically isolated from other ones of the contact pads 518 of the substrate and can be connected to ground (not shown) to enable the conductive cover 404 to function as an electromagnetic shield.

The conductive cover 404 can be over the first base integrated circuit 520 and the second base integrated circuit 521. The conductive cover 404 can be on and across the horizontal side of the circuit encapsulation 502 facing away from the substrate first side 514. The conductive cover 404 can be on the circuit encapsulation 502 surrounding the first base integrated circuit 520 and the circuit encapsulation 502 surrounding the second base integrated circuit 521. The conductive cover 404 can enhance thermal dissipation of heat energy generated by the first base integrated circuit 520 and the second base integrated circuit 521.

A mountable integrated circuit 530 can be attached to the substrate 512 of the integrated circuit structure 510. The mountable integrated circuit 530 is defined as an active device having active circuitry fabricated thereon. As an example, the mountable integrated circuit 530 can be a semiconductor die, a thin semiconductor die, a wirebond die, or a flip chip.

The mountable integrated circuit 530 can be attached to the substrate second side 516 with device interconnects 532. The device interconnects are defined as conductive structures that provide electrical connection between elements, devices, and other structures. As an example, the device interconnects 532 can be solder balls, solder bumps, conductive pillars, or conductive bumps. The device interconnects 532 can be between the substrate second side 516 and the mountable integrated circuit 530.

A device encapsulation 534 can be on and cover the substrate second side 516. The device encapsulation 534 is defined as a protective cover having electrical and environmental insulating properties providing a hermetic seal. As an example, the device encapsulation 534 can be a molded encapsulation material, such as an epoxy molding compound or ceramic material.

The device encapsulation 534 can be on and surround the mountable integrated circuit 530. The device encapsulation 534 can fill the space between the mountable integrated circuit 530 and the substrate second side 516. The device encapsulation 534 can surround the device interconnects 532. The device encapsulation 534 can form a hermetic seal around the mountable integrated circuit 530 and the device interconnects 532. The device encapsulation 534 surrounding the device interconnects 532 and between the mountable integrated circuit 530 and the substrate 512 can form a molded underfill.

The device encapsulation 534 can have an encapsulation outer side 536. The encapsulation outer side 536 is defined as the side of the device encapsulation 534 facing away from the substrate 512 of the integrated circuit structure 510. The encapsulation outer side 536 can be parallel with the substrate second side 516.

Via structures 540 can be in and surrounded by the device encapsulation 534. The via structures 540 are defined as conductive structures in a protective cover that provide electrical connectivity and extend between a side of a substrate and a surface of the protective cover.

The via structures 540 can be attached to the substrate 512 of the integrated circuit structure 510 at one end of the via structures 540 and exposed from the device encapsulation 534 at the opposing end of the via structures 540. The via structures 540 can extend vertically through the device encapsulation 534. The via structures 540 can be adjacent to the vertical sides of the mountable integrated circuit 530.

The via structures 540 can be formed from two separate conductive structures including a via base 542 and a via extension 544. The via base 542 is defined as the portion of the via structures 540 that provides connection to electrical connection sites on a support structure. The via base 542 can be the portion of the via structures 540 on the substrate second side 516. As an example, the via base 542 can be a conductive bump, conductive post, or conductive pillar. As a further example, the via base 542 can be formed from conductive materials, such as solder, gold, gold alloys, silver, silver alloys, or other alloys.

The via base 542 can be electrically connected to the contact pads 518 exposed along the substrate second side 516. The via base 542 can protect the contact pads 518 from damage due to physical, mechanical, chemical, or other processing when forming the via structures 540 on the substrate 512.

For illustrative purposes, the via base 542 is shown having a rounded or circular geometric shape, although it is understood that the via base 542 can have a different shape. For example, the via base 542 can have a rectangular profile corresponding to a cylindrical or rectangular block shape in three dimensional space.

The via base 542 can have a length in the vertical dimension as measured from the substrate second side 516 to the portion of the via base 542 directly opposite the substrate second side 516. As an example, the via base 542 can have the length where the vertical length of the via structure 540 in the vertical direction, as measured from the substrate second side 516, is similar or equivalent to the distance between the substrate second side 516 and the side of the mountable integrated circuit 530 facing away from the substrate second side 516.

As a further example, the length of the via base 542 can be greater than the distance between the substrate second side 516 and the side of the mountable integrated circuit 530 facing away from the substrate second side 516. As a specific example, the length of the via base 542 can be increased to reduce the length of the via extension 544, which can reduce the manufacturing time when forming the via extension 544.

The via base 542 can connect the via extension 544 of the via structures 540 to the integrated circuit structure 510. The via extension 544 can be the portion of the via structures 540 that extends between the via base 542 and the horizontal surface of the device encapsulation 534 facing away from the integrated circuit structure 510. The via base 542 and the via extension 544 can form a continuous conductive structure from the substrate 512 to the encapsulation outer side 536.

The via extension 544 can be attached to the via base 542 on one end and exposed from the device encapsulation 534 on the opposing end. The exposed portion of the via extension 544 can be coplanar with the encapsulation outer side 536 of the device encapsulation 534.

The via extension 544 can be a conductive structure formed from a hole or channel (not shown) filled with conductive material and extending from the encapsulation outer side 536 of the device encapsulation 534 to the via base 542. As an example, the via extension 544 can be made from conductive material, such as a conductive paste including copper or silver epoxy compounds, copper alloys, gold or gold alloys, or a low melting temperature high-wicking solder alloy. The via extension 544 can be made from a material having a melting point higher than that of the via base 542 or made from a material having higher resistant to flow and deformation at elevated temperatures relative to the via base 542.

As a further example, the hole or channel in the device encapsulation 534 can be formed by a laser ablation process, chemical etching, or mechanical processing, such as drilling. The interface between the device encapsulation 534 and the via extension 544 can have the characteristics of an encapsulation material removed. The characteristics of the encapsulation removed can include chemical residue, etching marks, groves, localized physical degradation or decomposition from exposure to high temperatures.

The via extension 544 can have a tapered shape along the vertical length of the via extension 544. A tapered shape is defined as a shape having a narrowing width with one end having a greater width than that of the opposing end. For example, the portion of the via extension 544 exposed from the device encapsulation 534 can have a width greater than that of the portion of the via extension 544 attached to the via base 542.

The via extension 544 can act as a barrier that maintains the position and form of the via base 542. For example, the via extension 544 can retain the shape of the via base 542 and prevent the flow or deformation of the via base 542 during processing of the integrated circuit packaging system 400 that would cause the via base 542 to melt or transition from a solid state to a liquid state, such as a solder reflow process.

External interconnects 546 can be connected to the via structures 540. The external interconnects 546 are defined as conductive connectors that provide connectivity between a packaging system and other devices and components. As an example, the external interconnects 546 can be solder balls, solder bumps, conductive pillars, or conductive bumps. The external interconnects 546 can connect the integrated circuit packaging system 400 to a next system level down (not shown). The external interconnects 546 can be attached on the portion of the via structures 540 exposed along the encapsulation outer side 536.

It has been discovered that the first base integrated circuit 520 and the second base integrated circuit 521 attached to the substrate first side 514 and the mountable integrated circuit 530 attached to the substrate second side 516 increases package density and reduces overall package height by eliminating the need for additional mounting and connecting structures that reduce package density and increase overall package height.

It has also been discovered that the via structures 540 having the via base 542 on the contact pads 518 of the substrate 512 protects the contact pads 518 from processing when forming the via structures 540.

It has been further discovered that the via structures 540 having the via extension 544 maintains the connection integrity between the via base 542 and the contact pads 518 by retaining the shape of the via base 542, and thus connection to the contact pads 518, during reflow processes, such as connection of the external interconnects 246 to the via extension 244.

It has been further discovered that the via extension 544 having the tapered shape improves electrical connectivity by providing a broader connection surface between the via structures 540 and the external interconnects 546.

It has been further discovered that the via extension 544 having the tapered shape reduces the size of the via structures 540 by reducing the area of the attachment interface between the via extension 544 and the via base 542 compared to the wider end of the via extension 544, which reduces the size needed for the via base 542.

It has been further discovered that the device encapsulation 534 surrounding the device interconnects 532 and between the mountable integrated circuit 530 and the substrate 512 can form the molded underfill, which reduces processing time by eliminating an additional process step required to form a separate underfill.

It has been further discovered that the integrated circuit structure 510 having the first base integrated circuit 520 and the second base integrated circuit 521 attached to the substrate increases packaging density and functionality by increasing the number of active devices in the integrated circuit packaging system 400.

It has been further discovered that the circuit encapsulation 502 having the encapsulation gap 529 between the first base integrated circuit 520 and the second base integrated circuit 521 reduces processing and manufacturing time by reducing the amount of material needed to form the circuit encapsulation 502.

It has been further discovered that the conductive cover 404 improves performance of the integrated circuit packaging system 400 by enhancing thermal dissipation of the first base integrated circuit 520 and the second base integrated circuit 521 and providing protection from electromagnetic interference that can disrupt operation of the first base integrated circuit 520 and the second base integrated circuit 521.

Referring now to FIG. 6, therein is shown a cross-sectional view of an integrated circuit packaging system 600 as exemplified by the top view along line 2-2 of FIG. 1 in a third embodiment of the present invention. The cross-sectional view depicts an integrated circuit structure 610. The integrated circuit structure 610 is defined as a structure including an interposer and an active device having active circuitry thereon.

The integrated circuit structure 610 can include a substrate 612. The substrate 612 is defined as a rigid structure that provides support and connectivity for mounting other components and devices. As an example, the substrate 612 can be a laminated substrate or a ceramic substrate. As a further example, the laminated substrate can be a layered substrate having vias and intermetallic layers. As a specific example, the substrate 612 can be a printed circuit board.

The substrate 612 can have a substrate first side 614 and a substrate second side 616. The substrate first side 614 and the substrate second side 616 can be the opposing horizontal sides of the substrate 612 with the substrate second side 616 facing away from the substrate first side 614.

Contact pads 618 can be exposed along the substrate first side 614 and the substrate second side 616. The contact pads 618 are defined as conductive pads that provide electrical connectivity between the substrate 612 and other devices or structures.

The integrated circuit structure 610 can include a base integrated circuit 620 attached to the substrate 612. The base integrated circuit 620 is defined as an active device having active circuitry fabricated thereon. As an example, the base integrated circuit 620 can be a semiconductor die, a thin semiconductor die, a wirebond die, or a flip chip.

The base integrated circuit 620 can have a circuit active side 622. The circuit active side 622 is defined as the side of the base integrated circuit 620 having active circuitry fabricated thereon (not shown). The circuit active side 622 can face away from the substrate first side 614. The circuit active side 622 can be parallel with the substrate first side 614.

The base integrated circuit 620 can be attached to the substrate first side 614 with an adhesive 624. The adhesive 624 is defined as a material for physically bonding or adhering two or more components to each other. For example, the adhesive 624 can be an epoxy or polymer adhesive material, a B-stage or partially cured adhesive material, or a thermally conductive adhesive material. The adhesive 624 can be between the substrate first side 614 and the base integrated circuit 620.

Circuit interconnects 626 can connect the base integrated circuit 620 to the substrate 612. The circuit interconnects 626 are defined as conductive structures for providing electrical connection between elements, devices, and other structures. As an example, the circuit interconnects 626 can be bond wires or ribbon bond wires. The circuit interconnects 626 can be connected between the circuit active side 622 and the contact pads 618 exposed along the substrate first side 614.

The integrated circuit structure 610 can include a circuit encapsulation 602. The circuit encapsulation 602 is defined as a protective cover having electrical and environmental insulating properties providing a hermetic seal. As an example, the circuit encapsulation 602 can be a molded encapsulation material, such as an epoxy molding compound or ceramic material.

The circuit encapsulation 602 can be on and cover the substrate first side 614. The circuit encapsulation 602 can be on and surround the base integrated circuit 620 and the circuit interconnects 626. The circuit encapsulation 602 can form a hermetic seal around the base integrated circuit 620 and the circuit interconnects 626.

A mountable integrated circuit 630 can be attached to the substrate 612 of the integrated circuit structure 610. The mountable integrated circuit 630 is defined as an active device having active circuitry fabricated thereon. As an example, the mountable integrated circuit 630 can be a semiconductor die, a thin semiconductor die, a wirebond die, or a flip chip.

The mountable integrated circuit 630 can be attached to the substrate second side 616 with device interconnects 632. The device interconnects are defined as conductive structures that provide electrical connection between elements, devices, and other structures. As an example, the device interconnects 632 can be solder balls, solder bumps, conductive pillars, or conductive bumps. The device interconnects 632 can be between the substrate second side 616 and the mountable integrated circuit 630.

A device encapsulation 634 can be on and cover the substrate second side 616. The device encapsulation 634 is defined as a protective cover having electrical and environmental insulating properties providing a hermetic seal. As an example, the device encapsulation 634 can be a molded encapsulation material, such as an epoxy molding compound or ceramic material.

The device encapsulation 634 can be on and surround the mountable integrated circuit 630. The device encapsulation 634 can fill the space between the mountable integrated circuit 630 and the substrate second side 616. The device encapsulation 634 can surround the device interconnects 632. The device encapsulation 634 can form a hermetic seal around the mountable integrated circuit 630 and the device interconnects 632. The device encapsulation 634 surrounding the device interconnects 632 and between the mountable integrated circuit 630 and the substrate 612 can form a molded underfill.

The device encapsulation 634 can have an encapsulation outer side 636. The encapsulation outer side 636 is defined as the side of the device encapsulation 634 facing away from the substrate 612 of the integrated circuit structure 610. The encapsulation outer side 636 can be parallel with the substrate second side 616.

The device encapsulation 634 can include an encapsulation recess 638. The encapsulation recess 638 can be in the device encapsulation 634 at the encapsulation outer side 636. The horizontal side of the mountable integrated circuit 630 facing away from the integrated circuit structure 610 can be exposed in the encapsulation recess 638.

Via structures 640 can be in and surrounded by the device encapsulation 634. The via structures 640 are defined as conductive structures in a protective cover that provide electrical connectivity and extend between a side of a substrate and a surface of the protective cover.

The via structures 640 can be attached to the substrate 612 of the integrated circuit structure 610 at one end of the via structures 640 and exposed from the device encapsulation 634 at the opposing end of the via structures 640. The exposed portion of the via structures 640 can be coplanar with the encapsulation outer side 636 of the device encapsulation 634.

The via structures 640 can extend vertically through the device encapsulation 634. The via structures 640 can be adjacent to the vertical sides of the mountable integrated circuit 630.

The via structures 640 can be a conductive structure formed from a hole or channel (not shown) filled with conductive material and extending from the encapsulation outer side 636 of the device encapsulation 634 to the substrate 612. As an example, the via structures 640 can be made from conductive material, such as a conductive paste including copper or silver epoxy compounds, copper alloys, gold or gold alloys, or a low melting temperature high-wicking solder alloy.

As a further example, the hole or channel in the device encapsulation 634 can be formed by a laser ablation process, chemical etching, or mechanical processing, such as drilling. The interface between the device encapsulation 634 and the via structures 640 can have the characteristics of an encapsulation material removed. The characteristics of the encapsulation removed can include chemical residue, etching marks, groves, localized physical degradation or decomposition from exposure to high temperatures.

The via structures 640 can have a tapered shape along the vertical length of the via structures 640. A tapered shape is defined as a shape having a narrowing width with one end having a greater width than that of the opposing end. For example, the portion of the via structures 640 exposed from the device encapsulation 634 can have a width greater than that of the portion of the via structure 640 attached to the substrate 612.

External interconnects 646 can be connected to the via structures 640. The external interconnects 646 are defined as conductive connectors that provide connectivity between a packaging system and other devices and components. As an example, the external interconnects 646 can be solder balls, solder bumps, conductive pillars, or conductive bumps. The external interconnects 646 can connect the integrated circuit packaging system 600 to a next system level down (not shown). The external interconnects 646 can be attached on the portion of the via structures 640 exposed along the encapsulation outer side 636.

It has been discovered that the base integrated circuit 620 attached to the substrate first side 614 and the mountable integrated circuit 630 attached to the substrate second side 616 increases package density and reduces overall package height by eliminating the need for additional mounting and connecting structures that reduce package density and increase overall package height.

It has been further discovered that the via structures 640 having the tapered shape improves electrical connectivity by providing a broader connection surface between the via structures 640 and the external interconnects 646.

It has been further discovered that the device encapsulation 634 surrounding the device interconnects 632 and between the mountable integrated circuit 630 and the substrate 612 can form the molded underfill, which reduces processing time by eliminating an additional process step required to form a separate underfill.

It has further been discovered that the mountable integrated circuit 630 exposed from the encapsulation recess 638 of the device encapsulation 634 enhances dissipation of thermal energy generated by the mountable integrated circuit 630 which increases performance and stability of the mountable integrated circuit 630.

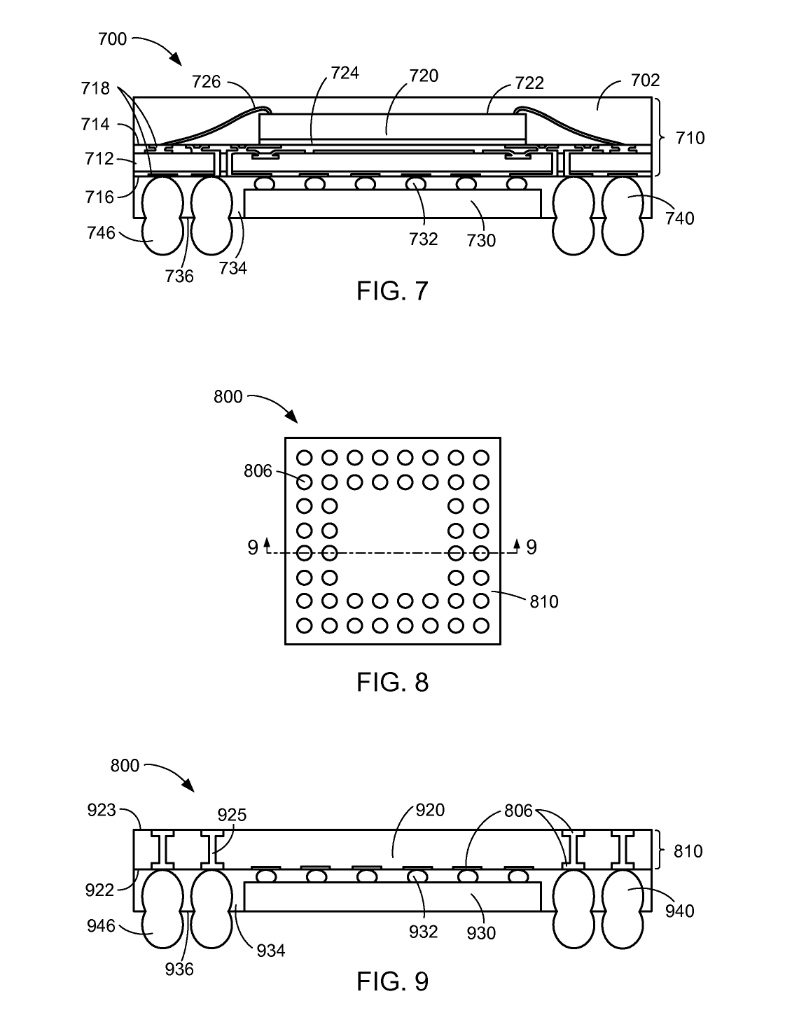

Referring now to FIG. 7, therein is shown a cross-sectional view of an integrated circuit packaging system 700 as exemplified by the top view along line 2-2 of FIG. 1 in a fourth embodiment of the present invention. The cross-sectional view depicts an integrated circuit structure 710. The integrated circuit structure 710 is defined as a structure including an interposer and an active device having active circuitry thereon.

The integrated circuit structure 710 can include a substrate 712. The substrate 712 is defined as a rigid structure that provides support and connectivity for mounting other components and devices. As an example, the substrate 712 can be a laminated substrate or a ceramic substrate. As a further example, the laminated substrate can be a layered substrate having vias and intermetallic layers. As a specific example, the substrate 712 can be a printed circuit board.

The substrate 712 can have a substrate first side 714 and a substrate second side 716. The substrate first side 714 and the substrate second side 716 can be the opposing horizontal sides of the substrate 712 with the substrate second side 716 facing away from the substrate first side 714.

Contact pads 718 can be exposed along the substrate first side 714 and the substrate second side 716. The contact pads 718 are defined as conductive pads that provide electrical connectivity between the substrate 712 and other devices or structures.

The integrated circuit structure 710 can include a base integrated circuit 720 attached to the substrate 712. The base integrated circuit 720 is defined as an active device having active circuitry fabricated thereon. As an example, the base integrated circuit 720 can be a semiconductor die, a thin semiconductor die, a wirebond die, or a flip chip.

The base integrated circuit 720 can have a circuit active side 722. The circuit active side 722 is defined as the side of the base integrated circuit 720 having active circuitry fabricated thereon (not shown). The circuit active side 722 can face away from the substrate first side 714. The circuit active side 722 can be parallel with the substrate first side 714.

The base integrated circuit 720 can be attached to the substrate first side 714 with an adhesive 724. The adhesive 724 is defined as a material for physically bonding or adhering two or more components to each other. For example, the adhesive 724 can be an epoxy or polymer adhesive material, a B-stage or partially cured adhesive material, or a thermally conductive adhesive material. The adhesive 724 can be between the substrate first side 714 and the base integrated circuit 720.

Circuit interconnects 726 can connect the base integrated circuit 720 to the substrate 712. The circuit interconnects 726 are defined as conductive structures for providing electrical connection between elements, devices, and other structures. As an example, the circuit interconnects 726 can be bond wires or ribbon bond wires. The circuit interconnects 726 can be connected between the circuit active side 722 and the substrate first side 714.

The integrated circuit structure 710 can include a circuit encapsulation 702. The circuit encapsulation 702 can be on and cover the substrate first side 714. The circuit encapsulation 702 can be on and surround the base integrated circuit 720 and the circuit interconnects 726. The circuit encapsulation 702 can form a hermetic seal around the base integrated circuit 720 and the circuit interconnects 726.

A mountable integrated circuit 730 can be attached to the substrate 712 of the integrated circuit structure 710. The mountable integrated circuit 730 is defined as an active device having active circuitry fabricated thereon. As an example, the mountable integrated circuit 730 can be a semiconductor die, a thin semiconductor die, a wirebond die, or a flip chip.

The mountable integrated circuit 730 can be attached to the substrate second side 716 with device interconnects 732. The device interconnects are defined as conductive structures that provide electrical connection between elements, devices, and other structures. As an example, the device interconnects 732 can be solder balls, solder bumps, conductive pillars, or conductive bumps. The device interconnects 732 can be between the substrate second side 716 and the mountable integrated circuit 730.

A device encapsulation 734 can be on and cover the substrate second side 716. The device encapsulation 734 is defined as a protective cover having electrical and environmental insulating properties providing a hermetic seal. As an example, the device encapsulation 734 can be a molded encapsulation material, such as an epoxy molding compound or ceramic material.

The device encapsulation 734 can be on and surround the mountable integrated circuit 730. The device encapsulation 734 can fill the space between the mountable integrated circuit 730 and the substrate second side 716. The device encapsulation 734 can surround the device interconnects 732. The device encapsulation 734 can form a hermetic seal around the mountable integrated circuit 730 and the device interconnects 732. The device encapsulation 734 surrounding the device interconnects 732 and between the mountable integrated circuit 730 and the substrate 712 can form a molded underfill.

The device encapsulation 734 can have an encapsulation outer side 736. The encapsulation outer side 736 is defined as the side of the device encapsulation 734 facing away from the substrate 712 of the integrated circuit structure 710. The encapsulation outer side 736 can be parallel with the substrate second side 716.

The side of the mountable integrated circuit 730 parallel with and facing away from the substrate second side 716 can be exposed from the device encapsulation 734 along the encapsulation outer side 736. The exposed side of the mountable integrated circuit 730 can be coplanar with the encapsulation outer side 736.

Via structures 740 can be in and surrounded by the device encapsulation 734. The via structures 740 are defined as conductive structures in a protective cover that provide electrical connectivity and extend between a side of a substrate and a surface of the protective cover. As an example, the via structures 740 can be conductive bumps, conductive posts, or conductive pillars. As a further example, the via structures 740 can be formed from conductive materials, such as solder, gold, gold alloys, silver, silver alloys, or other alloys.

The via structures 740 can be attached to the substrate 712 of the integrated circuit structure 710 at one end of the via structures 740 and exposed from the device encapsulation 734 at the opposing end of the via structures 740. The via structures 740 can be exposed along the encapsulation outer side 736. The exposed portion of the via structures 740 can be coplanar with the encapsulation outer side 736 and the exposed side of the mountable integrated circuit 730.

The via structures 740 can extend vertically through the device encapsulation 734. The via structures 740 can be adjacent to the vertical sides of the mountable integrated circuit 730. The via structures 740 can be electrically connected to the contact pads 718 exposed along the substrate second side 716.

External interconnects 746 can be connected to the via structures 740. The external interconnects 746 are defined as conductive connectors that provide connectivity between a packaging system and other devices and components. As an example, the external interconnects 746 can be solder balls, solder bumps, conductive pillars, or conductive bumps.

The external interconnects 746 can connect the integrated circuit packaging system 700 to a next system level down (not shown). The external interconnects 746 can be attached on the portion of the via structures 740 exposed along the encapsulation outer side 736. For example, the external interconnects 746 can be combine with the via structures 740 to form a single conductive structure. As a specific example, the external interconnects 746 can be combine with the via structures 740 during a reflow process.

It has been discovered that the base integrated circuit 720 attached to the substrate first side 714 and the mountable integrated circuit 730 attached to the substrate second side 716 increases package density and reduces overall package height by eliminating the need for additional mounting and connecting structures that reduce package density and increase overall package height.

It has been further discovered that the device encapsulation 734 surrounding the device interconnects 732 and between the mountable integrated circuit 730 and the substrate 712 can form the molded underfill, which reduces processing time by eliminating an additional process step required to form a separate underfill.

It has further been discovered that the mountable integrated circuit 730 exposed along the encapsulation outer side 736 of the device encapsulation 734 enhances dissipation of thermal energy generated by the mountable integrated circuit 730 which increases performance and stability of the mountable integrated circuit 730.

It has been further discovered that exposing the mountable integrated circuit 730 and the via structures 740 from the device encapsulation 734 with exposed portions of the mountable integrated circuit 730 and the via structures 740 coplanar with the encapsulation outer side 736 reduces the vertical package profile by removing the portion of the device encapsulation 734 covering the mountable integrated circuit 730.

Referring now to FIG. 8 therein is shown a top view of an integrated circuit packaging system 800 in a fifth embodiment of the present invention. The top view depicts an integrated circuit structure 810. The integrated circuit structure 810 is defined as a structure including an interposer and an active device having active circuitry thereon. For example, the integrated circuit structure 810 can be a semiconductor substrate or a semiconductor die having vias and active circuitry fabricated thereon, such as a through silicon via.

The integrated circuit structure 810 can include circuit via pads 806 exposed along a side of the integrated circuit structure 810. The circuit via pads 806 are defined as conductive pads that provide electrical connectivity between the integrated circuit structure 810 and other devices or structures. The circuit via pads 806 can be arranged in rows along the perimeter of the integrated circuit structure 810.

For illustrative purposes, the integrated circuit packaging system 800 is shown having the circuit via pads 806 arranged in dual rows along the perimeter of the integrated circuit structure 810, although it is understood that the circuit via pads 806 can be arranged differently. For example, the circuit via pads 806 can be arranged in a single row or can include three or more rows. In a further example, the circuit via pads 806 can be arranged in a staggered configuration.

Referring now to FIG. 9, therein is shown a cross-sectional view of the integrated circuit packaging system 800 along line 9-9 of FIG. 8. The cross-sectional view depicts the integrated circuit structure 810. The integrated circuit structure 810 can be a base integrated circuit 920. The base integrated circuit 920 is defined as an active device having active circuitry fabricated thereon.

The integrated circuit structure 810 can have a circuit active side 922 and a circuit non-active side 923. The circuit active side 922 is defined as the horizontal side of the integrated circuit structure 810 having active circuitry (not shown) fabricated thereon. The circuit non-active side 923 is defined as the side of the integrated circuit structure 810 opposite and facing away from the circuit active side 922. The circuit via pads 806 can be exposed along the circuit active side 922 and the circuit non-active side 923.

The integrated circuit structure 810 can include circuit vias 925. The circuit vias 925 are defined as channels or holes filled with conductive material that extends from one surface of a semiconductor device to an opposite surface of the semiconductor device. The circuit vias 925 can be filled with a conductive material. For example, the circuit vias 925 can be filled with conductive materials such as copper, a copper alloy, gold, a gold alloy, nickel, a nickel alloy, or other alloys.

The circuit vias 925 can extend through the circuit vias 925 from the circuit active side 922 to the circuit non-active side 923. The circuit vias 925 can connect between one of the circuit via pads 806 at the circuit active side 922 and another one of the circuit via pads 806 at the circuit non-active side 923.

A mountable integrated circuit 930 can be attached to the integrated circuit structure 810. The mountable integrated circuit 930 is defined as an active device having active circuitry fabricated thereon. As an example, the mountable integrated circuit 930 can be a semiconductor die, a thin semiconductor die, a wirebond die, or a flip chip.

The mountable integrated circuit 930 can be attached to the circuit active side 922 with device interconnects 932. The device interconnects are defined as conductive structures that provide electrical connection between elements, devices, and other structures. As an example, the device interconnects 932 can be solder balls, solder bumps, conductive pillars, or conductive bumps. The device interconnects 932 can be between the circuit active side 922 and the mountable integrated circuit 930.

A device encapsulation 934 can be on and cover the circuit active side 922. The device encapsulation 934 is defined as a protective cover having electrical and environmental insulating properties providing a hermetic seal. As an example, the device encapsulation 934 can be a molded encapsulation material, such as an epoxy molding compound or ceramic material.

The device encapsulation 934 can be on and surround the mountable integrated circuit 930. The device encapsulation 934 can fill the space between the mountable integrated circuit 930 and the circuit active side 922. The device encapsulation 934 can surround the device interconnects 932. The device encapsulation 934 can form a hermetic seal around the mountable integrated circuit 930 and the device interconnects 932. The device encapsulation 934 surrounding the device interconnects 932 and between the mountable integrated circuit 930 and the integrated circuit structure 810 can form a molded underfill.

The device encapsulation 934 can have an encapsulation outer side 936. The encapsulation outer side 936 is defined as the side of the device encapsulation 934 facing away from the circuit active side 922. The encapsulation outer side 936 can be parallel with the circuit active side 922.

The side of the mountable integrated circuit 930 parallel with and facing away from the circuit active side 922 can be exposed from the device encapsulation 934 along the encapsulation outer side 936. The exposed side of the mountable integrated circuit 930 can be coplanar with the encapsulation outer side 936.

Via structures 940 can be in and surrounded by the device encapsulation 934. The via structures 940 are defined as conductive structures in a protective cover that provide electrical connectivity and extend between a side of a substrate and a surface of the protective cover. As an example, the via structures 940 can be conductive bumps, conductive posts, or conductive pillars. As a further example, the via structures 940 can be formed from conductive materials, such as solder, gold, gold alloys, silver, silver alloys, or other alloys.

The via structures 940 can be attached to the circuit active side 922 of the integrated circuit structure 810 at one end of the via structures 940 and exposed from the device encapsulation 934 at the opposing end of the via structures 940. The via structures 940 can be exposed along the encapsulation outer side 936. The exposed portion of the via structures 940 can be coplanar with the encapsulation outer side 936 and the exposed side of the mountable integrated circuit 930.

The via structures 940 can extend vertically through the device encapsulation 934. The via structures 940 can be adjacent to the vertical sides of the mountable integrated circuit 930. The via structures 940 can be electrically connected to the circuit via pads 806 exposed along the circuit active side 922.

External interconnects 946 can be connected to the via structures 940. The external interconnects 946 are defined as conductive connectors that provide connectivity between a packaging system and other devices and components. As an example, the external interconnects 946 can be solder balls, solder bumps, conductive pillars, or conductive bumps.

The external interconnects 946 can connect the integrated circuit packaging system 100 to a next system level down (not shown). The external interconnects 946 can be attached on the portion of the via structures 940 exposed along the encapsulation outer side 936. For example, the external interconnects 946 can be combine with the via structures 940 to form a single conductive structure. As a specific example, the external interconnects 946 can be combine with the via structures 940 during a reflow process.

It has been discovered that the device encapsulation 934 surrounding the device interconnects 932 and between the mountable integrated circuit 930 and the integrated circuit structure 810 can form the molded underfill, which reduces processing time by eliminating an additional process step required to form a separate underfill.

It has further been discovered that the mountable integrated circuit 930 exposed along the encapsulation outer side 936 of the device encapsulation 934 enhances dissipation of thermal energy generated by the mountable integrated circuit 930 which increases performance and stability of the mountable integrated circuit 930.

It has been further discovered that exposing the mountable integrated circuit 930 and the via structures 940 from the device encapsulation 934 with exposed portions of the mountable integrated circuit 930 and the via structures 940 coplanar with the encapsulation outer side 936 reduces the vertical package profile by removing the portion of the device encapsulation 934 covering the mountable integrated circuit 930.

It has been further discovered that the mountable integrated circuit 930 attached to the base integrated circuit 920 of the integrated circuit structure 810 reduces the vertical package profile by eliminating the need for an interposer structure.

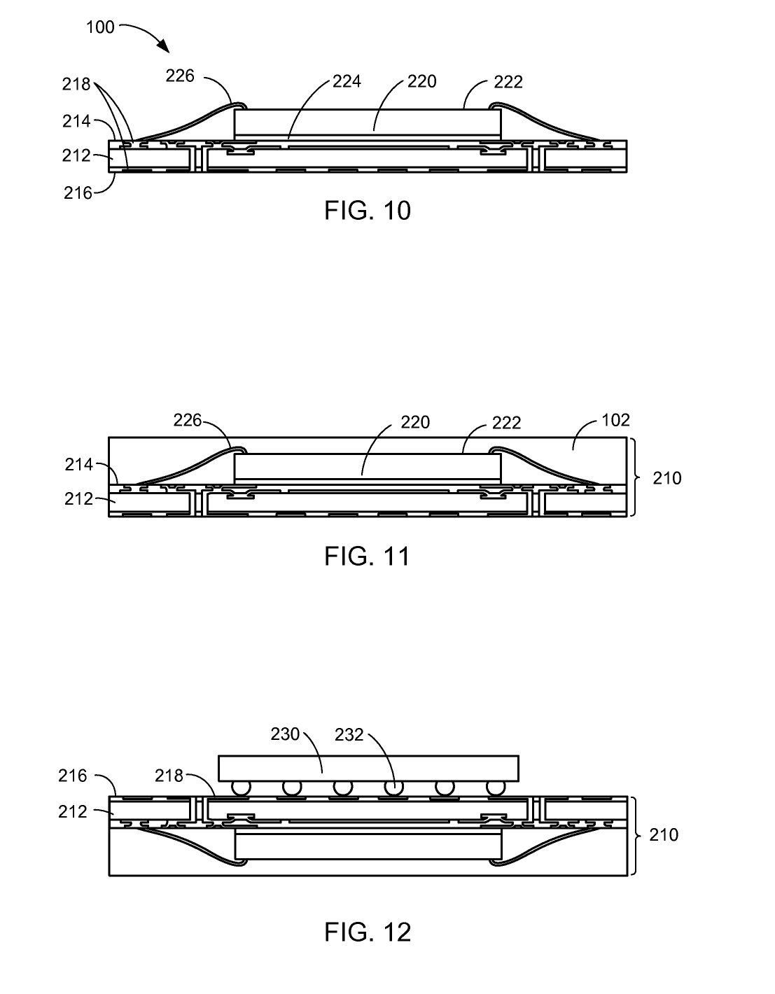

Referring now to FIG. 10, therein is shown a cross-sectional view of a portion of the integrated circuit packaging system 100 along line 2-2 of FIG. 1 in an attaching phase. The portion of the integrated circuit packaging system 100 depicts the substrate 212 of the integrated circuit structure of FIG. 2.

The substrate 212 can have a substrate first side 214 and the substrate second side 216. The substrate first side 214 and the substrate second side 216 can be the opposing horizontal sides of the substrate 212 with the substrate second side 216 facing away from the substrate first side 214. The contact pads 218 can be exposed along the substrate first side 214 and the substrate second side 216.

The base integrated circuit 220 can be attached to the substrate first side 214 with the adhesive 224. The adhesive 224 can be between the substrate first side 214 and the base integrated circuit 220.

The base integrated circuit 220 can be electrically connected to the substrate 212 with the circuit interconnects 226. The circuit interconnects 226 can be connected between the circuit active side 222 of the base integrated circuit 220 and the contact pads 218 exposed long the substrate first side 214.

Referring now to FIG. 11, therein is shown the structure of FIG. 10 in a molding phase. The circuit encapsulation 102 can be formed on and cover the substrate first side 214 of the substrate 212. The circuit encapsulation 102 can be on the circuit active side 222 and surround the base integrated circuit 220 and the circuit interconnects 226. The circuit encapsulation 102 can form a hermetic seal around the base integrated circuit 220 and the circuit interconnects 226. Forming the circuit encapsulation 102 can form the integrated circuit structure 210.

Referring now to FIG. 12, therein is shown the structure of FIG. 11 in an attaching phase. The attaching phase depicts structure of FIG. 11 in an inverted configuration. The integrated circuit structure 210 can be inverted to attach the mountable integrated circuit 230 to the substrate 212.

The mountable integrated circuit 230 can be electrically connected to the contact pads 218 exposed along the substrate second side 216 with the device interconnects 232. The device interconnects 232 can be between the mountable integrated circuit 230 and the substrate second side 216.

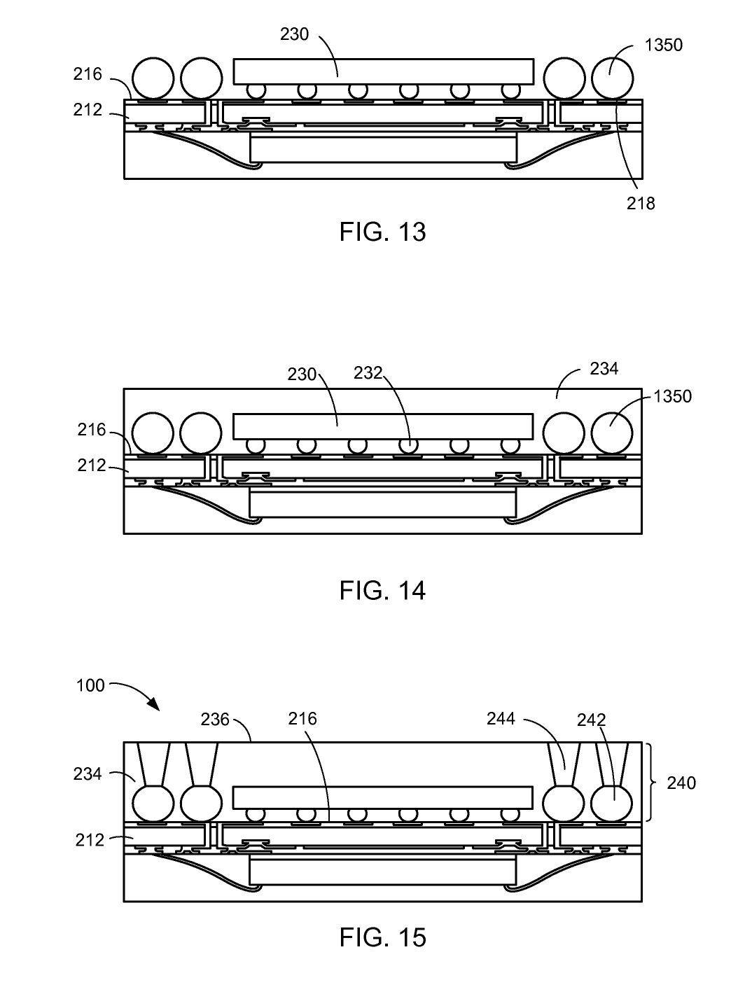

Referring now to FIG. 13, therein is shown the structure of FIG. 12 in a further attaching phase. Base connectors 1350 can be attached to the substrate second side 216. The base connectors 1350 are defined as a conductive structure for providing electrical connection to a support or mounting structure. The base connectors 1350 can be formed from the same or similar material to that of the via base 242 of FIG. 2.

The base connectors 1350 can be attached to the contact pads 218 exposed along the substrate second side 216 of the substrate 212. The base connectors 1350 can be adjacent to the vertical side of the mountable integrated circuit 230.

The base connectors 1350 can be the precursor to the via base 242 prior to formation of the device encapsulation 234 of FIG. 2 and the via extension 244 of FIG. 2.

Referring now to FIG. 14, therein is shown the structure of FIG. 13 in a further molding phase. The device encapsulation 234 can be formed on and cover the substrate second side 216. The device encapsulation 234 can be formed on and surround the base connectors 1350.

The device encapsulation 234 can be formed on and surround the mountable integrated circuit 230. The device encapsulation 234 can be formed to fill the space between the mountable integrated circuit 230 and the substrate second side 216.

The device encapsulation 234 can be formed to surround the device interconnects 232. The device encapsulation 234 can form a hermetic seal around the mountable integrated circuit 230 and the device interconnects 232. The device encapsulation 234 surrounding the device interconnects 232 and between the mountable integrated circuit 230 and the substrate 212 can form a molded underfill.

Referring now to FIG. 15, therein is shown the structure of FIG. 14 in a forming the integrated circuit packaging system 100 of FIG. 1. The via extension 244 can be formed through the device encapsulation 234 to the base connectors 1350 of FIG. 14. Forming the via extension 244 connected to the base connectors 1350 can form the via base 242 and the via structures 240. The via structures 240 can include the via extension 244 and the via base 242.

The via extension 244 can be formed in a number of different ways. For example, a hole or channel (not shown) can be formed in the device encapsulation 234 to the via base 242. The hole or channel can be formed by a laser ablation process, chemical etching, or mechanical processing, such as drilling. Forming the hole or channel in the device encapsulation 234 can create characteristics of an encapsulation material removed. The characteristics of the encapsulation removed can include chemical residue, etching marks, groves, localized physical degradation or decomposition from exposure to high temperatures.

As a further example of forming the via extension 244, the hole or channel can be filled with conductive material, such as a conductive paste including copper or silver epoxy compounds, copper alloys, gold or gold alloys, or a low melting temperature high-wicking solder alloy. The hole or channel can be filled in a number of different ways. For example, the conductive material used to form the via extension 244 can be electroplated or electro less plated. As a further example, a process, such as sputtering, physical vapor deposition, or chemical can be used.

The portion of the via extension 244 exposed from the device encapsulation 234 can be planarized to be coplanar with the side of the device encapsulation 234 facing away from the substrate second side 216 of the substrate 212. Planarizing the device encapsulation 234 can form the encapsulation outer side 236. The encapsulation outer side 236 can be formed parallel to the substrate second side 216.

The via extension 244 and the device encapsulation 234 can be planarized in a number of different ways. For example, physical processes, such as mechanical grinding, or chemical processes, such as chemical etching, can be used to form the via extension 244 coplanar with the encapsulation outer side 236.

The external interconnects 246 of FIG. 2 can be connected to the via structures 240. The external interconnects 246 can be attached to the portion of the via extension 244 exposed along the encapsulation outer side 236. Attaching the external interconnects 246 can form the integrated circuit packaging system 100.

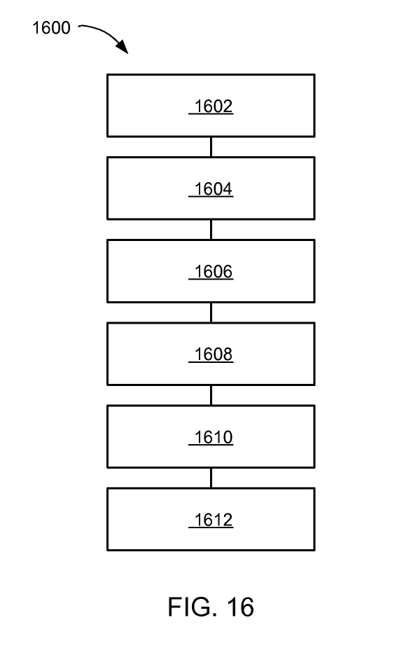

Referring now to FIG. 16, therein is shown a flow chart of a method 1600 of manufacture of the integrated circuit packaging system in a further embodiment of the present invention. The method 1600 includes: providing a substrate having a substrate first side and a substrate second side opposite the substrate first side in a block 1602; attaching a base integrated circuit to the substrate first side in a block 1604; attaching a mountable integrated circuit to the substrate second side in a block 1606; attaching a via base to the substrate second side adjacent the mountable integrated circuit in a block 1608; forming a device encapsulation surrounding the via base and the mountable integrated circuit in a block 1610; and forming a via extension through the device encapsulation and attached to the via base, the via extension exposed from the device encapsulation in a block 1612.

Thus, it has been discovered that the integrated circuit packaging system of the present invention furnishes important and heretofore unknown and unavailable solutions, capabilities, and functional aspects for base conductive vias. The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit packaging systems/fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a substrate having a substrate first side and a substrate second side opposite the substrate first side;
attaching a base integrated circuit to the substrate first side;
attaching a mountable integrated circuit to the substrate second side;
attaching a via base to the substrate second side adjacent the mountable integrated circuit;
forming a device encapsulation surrounding the via base and the mountable integrated circuit; and
forming a via extension through the device encapsulation and attached to the via base, the via extension exposed from the device encapsulation.

2. The method as claimed in claim 1 wherein forming the via extension includes forming the via extension having a tapered shape with the width of end of the via extension exposed from the device encapsulation greater than the width of the end of the via extension attached to the via base.

3. The method as claimed in claim 1 further comprising forming a circuit encapsulation on the substrate first side and surrounding the base integrated circuit.

4. The method as claimed in claim 1 wherein forming the device encapsulation includes filling the space between the mountable integrated circuit and the substrate second side with the device encapsulation.

5. The method as claimed in claim 1 further comprising attaching a conductive cover to the substrate first side and over the base integrated circuit.

6. A method of manufacture of an integrated circuit packaging system comprising:
providing a substrate having a substrate first side and a substrate second side opposite the substrate first side;
attaching a base integrated circuit to the substrate first side;
attaching a mountable integrated circuit to the substrate second side;
attaching a via base to the substrate second side adjacent the mountable integrated circuit;
forming a device encapsulation, having an encapsulation outer side facing away from the substrate second side, on the substrate second side surrounding the via base and the mountable integrated circuit; and
forming a via extension through the device encapsulation and attached to the via base, the via extension exposed from the device encapsulation along the encapsulation outer side.

7. The method as claimed in claim 6 wherein forming the via extension includes forming the via extension exposed from the device encapsulation coplanar with the encapsulation outer side.

8. The method as claimed in claim 6 further comprising attaching a further base integrated circuit to the substrate first side and adjacent to the base integrated circuit.

9. The method as claimed in claim 6 further comprising attaching an external interconnect to the portion of the via extension exposed from the device encapsulation.

10. The method as claimed in claim 6 wherein attaching the mountable integrated circuit includes attaching a flip chip.

11. An integrated circuit packaging system comprising:
a substrate having a substrate first side and a substrate second side opposite the substrate first side;
a base integrated circuit attached to the substrate first side;
a mountable integrated circuit attached to the substrate second side;
a via base attached to the substrate second side adjacent the mountable integrated circuit;
a device encapsulation surrounding the via base and the mountable integrated circuit; and
a via extension through the device encapsulation and attached to the via base, the via extension exposed from the device encapsulation.

12. The system as claimed in claim 11 wherein the via extension has a tapered shape with the width of end of the via extension exposed from the device encapsulation greater than the width of the end of the via extension attached to the via base.

13. The system as claimed in claim 11 further comprising a circuit encapsulation on the substrate first side and surrounding the base integrated circuit.

14. The system as claimed in claim 11 wherein the device encapsulation fills the space between the mountable integrated circuit and the substrate second side.

15. The system as claimed in claim 11 further comprising a conductive cover attached to the substrate first side and over the base integrated circuit.

16. The system as claimed in claim 11 wherein:
the device encapsulation includes an encapsulation outer side facing away from the substrate second side; and
the via extension is exposed from the device encapsulation along the encapsulation outer side.

17. The system as claimed in claim 16 wherein the portion of the via extension exposed from the device encapsulation is coplanar with the encapsulation outer side.

18. The system as claimed in claim 16 further comprising a further base integrated circuit attached to the substrate first side adjacent to the base integrated circuit.

19. The system as claimed in claim 16 further comprising an external interconnect attached to the portion of the via extension exposed from the device encapsulation.

20. The system as claimed in claim 16 wherein the mountable integrated circuit includes a flip chip.
